(19) United States
(12) Patent Application Publication
(10) Pub. No.: US 2011/0001945 A1
(43) Pub. Date: Jan. 6, 2011

(54) PROJECTION OPTICAL SYSTEM, EXPOSURE APPARATUS, AND ASSEMBLY METHOD THEREOF

(76) Inventor: Masayuki SHIRAISHI, Kumagaya-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/826,213

(22) Filed: Jun. 29, 2010

Related U.S. Application Data
(60) Provisional application No. 61/213,675, filed on Jul. 1, 2009.

(51) Int. Cl. G03F 7/20; B23P 19/00; G02B 7/198; G03B 27/70

(52) U.S. Cl. 355/67; 29/426.2; 359/862; 355/77

(57) ABSTRACT

According to one embodiment, an assembly method of a projection optical system, including a lower tube and an upper tube, comprises: storing a relative positional relation between the lower tube and the upper tube in a state in which an optical characteristic of the projection optical system is adjusted; disassembling the lower tube and the upper tube; and adjusting relative positions of the lower tube and the upper tube, based on the stored relative positional relation, in next fixing the lower tube and the upper tube to each other.

### CROSS-REFERENCE TO RELATED APPLICATIONS

This application is based upon and claims the benefit of priority to from Provisional Application No. 61/213,675 filed on Jul. 1, 2009, the entire contents of which are incorporated herein by reference.

### BACKGROUND

1. Field

One embodiment of the invention relates to a projection optical system having a plurality of optical elements, an assembly method of the projection optical system, an exposure apparatus provided with the projection optical system, and a device manufacturing method using the exposure apparatus.

2. Description of the Related Art

In general, a projection optical system is provided in an exposure apparatus used in a photolithography step of manufacturing various devices (electronic devices) such as semiconductor devices. The projection optical system is required to adjust relative positional relations among a plurality of optical elements into a predetermined state with high accuracy, in order to achieve a required optical characteristic (imaging characteristic or the like). The adjustment accuracy necessary for the positional relations is of the sub-micron order in the exposure apparatus in which the wavelength of exposure light ranges from the far ultraviolet region to the vacuum ultraviolet region. Furthermore, the nm order is required for the exposure apparatus (EUV exposure apparatus) using Extreme Ultraviolet Light (hereinafter referred to as BIN light) at the wavelength of not more than about 100 nm as exposure light.

For efficiently carrying out assembly and adjustment of the projection optical system required to highly accurately adjust the positional relations among the plurality of optical elements as described above, the technology described in Japanese Patent Application Laid-Open No. 2004-128307 is known as an example of the conventional technology. Namely, the conventional technology described in Japanese Patent Application Laid-Open No. 2004-128307 was to divide the cylinder of the projection optical system into a plurality of partial tubes each having one or more of the plurality of optical elements, to adjust positional relations among internal optical elements in each of the partial tubes, in an optical system manufacturing factory, and thereafter to stack the plurality of partial tubes and perform overall adjustment until the required optical characteristic is achieved. The projection optical system after completion of the assembly and adjustment as described above was transported, for example, to a device manufacturing factory, which is an installation place of the exposure apparatus, in that state to be fixed to a predetermined frame of the exposure apparatus.

Recently, for exposure of finer patterns, the distance between the object plane and the image plane of the projection optical system tends to become longer. In conjunction therewith, the overall length of the cylinder of the projection optical system also tends to become longer. With the projection optical systems having the long overall length, it is sometimes the case that it is difficult to transport the projection optical system in the original state to another place because of freight restrictions of airplane or the like.

Furthermore, during installing the projection optical system on the predetermined frame of the exposure apparatus, the projection optical system needs to be hung, for example, with a crane. However, in the case that the overall length of the projection optical system is long, it becomes substantially difficult to assemble the exposure apparatus, e.g., it becomes necessary to make, for example, a ceiling of the device manufacturing factory where the exposure apparatus is installed, high.

On the other hand, it can be contemplated that the projection optical system once assembled is disassembled into a plurality of partial tubes and then transported to the installation place. However, when the plurality of partial tubes disassembled are again stacked and assembled, it is necessary to repeat the assembly and adjustment of the projection optical system until the required optical characteristic is achieved. That is, the time to a start of operation of the exposure apparatus becomes longer.

### SUMMARY

According to an embodiment of the invention, an assembling method assembles a projection optical system, which includes a plurality of optical elements, a first partial tube holding a first optical element out of the plurality of optical elements, and a second partial tube holding a second optical element out of the plurality of optical elements and which is configured to form an image of a pattern on a first surface, on a second surface, and comprises: storing a relative positional relation between the first partial tube and the second partial tube, the relative positional relation being measured in a state in which the second partial tube is fixed to the first partial tube and in which an optical characteristic of the projection optical system is adjusted; disassembling the first partial tube and the second partial tube; adjusting relative positions of the first partial tube and the second partial tube, based on the relative positional relation stored, in again fixing the first partial tube and the second partial tube disassembled, to each other; and fixing the second partial tube to the first partial tube.

According to an embodiment of the invention, a projection optical system is configured to form an image of a pattern on a first surface, on a second surface, and comprises a plurality of optical elements, a first partial tube, a second partial tube, and a memory device. The first partial tube holds a first optical element out of the plurality of optical elements. The second partial tube is fixed to the first partial tube and holds a second optical element out of the plurality of optical elements. The memory device stores a relative positional relation between the first partial tube and the second partial tube. The relative positional relation is measured in a state in which the second partial tube is fixed to the first partial tube and in which an optical characteristic of the projection optical system is adjusted.

According to an embodiment of the invention, an exposure apparatus is configured to expose an object through a projection optical system, which has a plurality of optical elements, a first partial tube holding a first optical element out of the plurality of optical elements, and a second partial tube fixed to the first partial tube and holding a second optical element out of the plurality of optical elements, and comprises a memory device, and an adjustment device. The memory device stores a relative positional relation between the first partial tube and the second partial tube. The relative positional relation is measured in a state in which the second partial tube is fixed to the first partial tube and in which an optical characteristic of the projection optical system is adjusted. The adjustment device adjusts relative positions of the first partial tube and the second partial tube, based on the relative positional relation stored in the memory device.

For purposes of summarizing the invention, certain aspects, advantages, and novel features of the invention have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary sectional view showing a schematic configuration of an exposure apparatus as an example of embodiments;

FIG. 2A is an exemplary sectional view showing a projection optical system after completion of assembly and adjustment and FIG. 2B is an exemplary sectional view along line BB in FIG. 2A;

FIG. 3 is an exemplary sectional view showing a state in which the projection optical system is disassembled (or separated);

FIG. 4 is an exemplary sectional view showing a state in which a lower tube of the projection optical system is installed on an optical frame;

FIG. 5A is an exemplary sectional view showing a state in which an upper tube is installed on the lower tube of the projection optical system and FIG. 5B is an exemplary sectional view along line CC in FIG. 5A;

FIG. 6 is an exemplary flowchart showing an example of assembly and adjustment steps of the projection optical system; and

FIG. 7 is an exemplary flowchart showing an example of manufacturing steps of electronic devices.

### DETAILED DESCRIPTION

Various embodiments according to the invention will be described hereinafter with reference to the accompanying drawings. In general, according to one embodiment of the invention, an assembling method assembles a projection optical system which includes a plurality of optical elements, a first partial tube holding a first optical element out of the plurality of optical elements, and a second partial tube holding a second optical element out of the plurality of optical elements and which is configured to form an image of a pattern on a first surface, on a second surface. For example, the assembling method comprises: storing a relative positional relation between the first partial tube and the second partial tube in a state in which the second partial tube is fixed to the first partial tube and in which an optical characteristic of the projection optical system is adjusted; disassembling the first partial tube and the second partial tube; adjusting relative positions of the first partial tube and the second partial tube, based on the relative positional relation stored, in again fixing the first partial tube and the second partial tube disassembled, to each other; and fixing the second partial tube to the first partial tube.

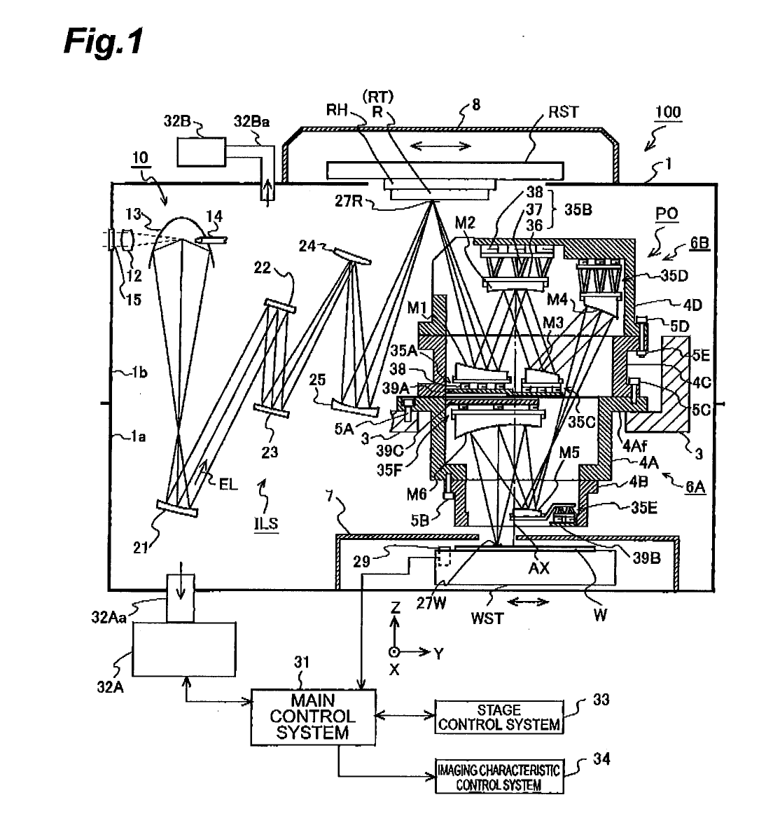

FIG. 1 is an exemplary sectional view schematically showing an overall configuration of exposure apparatus 100 according to the present embodiment. The exposure apparatus 100 is an EUV exposure apparatus using exposure light (illumination light for exposure) EL in the wavelength range of not more than about 100 nm and approximately 3 to 50 nm, e.g., EUV light (Extreme Ultraviolet Light) of 11 nm or 13 nm or the like. The exposure apparatus 100 is installed, for example, in a vacuum chamber 1 in a clean room in a semiconductor device manufacturing factory. In FIG. 1, the exposure apparatus 100 has a laser plasma light source 10 which generates pulses of exposure light EL, an illumination optical system ILS which illuminates an illumination region 27R on a pattern surface (lower surface herein) of a reticle R (mask) with the exposure light EL, a reticle stage RST which moves the reticle R, and a projection optical system PO which projects an image of a pattern in the illumination region 27R of the reticle R onto a wafer W (photosensitive substrate) coated with a resist (photosensitive material). Furthermore, the exposure apparatus 100 has a wafer stage WST which moves the wafer W, a main control system 31 including a computer for generally controlling the overall operation of the apparatus, and so on.

The present embodiment uses the EUV light as the exposure light EL. Therefore, the illumination optical system ILS and the projection optical system PO each are composed of a plurality of reflecting optical elements such as mirrors except for a specific filter and others (not shown), and the reticle R is also a reflective type. Each of the reflecting optical elements is made, for example, by highly accurately processing a surface of a member of quartz (or metal with high thermal resistance or the like) into a predetermined curved surface or plane and thereafter forming a multilayer film of molybdenum (Mo) and silicon (Si) (reflecting film for EUV light) on the processed surface so as to create a reflecting surface. The multilayer film may be another multilayer film of a combination of a material such as ruthenium (Ru) or rhodium (Rh) with a material such as Si, beryllium (Be), or carbon tetraboride (B4C). The reticle R is, for example, one made in such a manner that a multilayer film is formed on a surface of a quartz substrate to create a reflecting surface (reflecting film) and thereafter a pattern for transfer is formed of an absorbing layer of a material which absorbs the EUV light, such as tantalum (Ta), nickel (Ni), or chromium (Cr), on the reflecting surface.

For preventing absorption of the BUY light by gas, the exposure apparatus 100 is almost entirely housed in the vacuum chamber 1 of a box shape. The vacuum chamber 1 is equipped with large-scale vacuum pumps 32A, 32B, etc. for evacuating the space in the vacuum chamber 1 through exhaust pipes 32Aa, 32Ba, and so on. Furthermore, a plurality of sub-chambers (not shown) are also provided for further enhancing the degree of vacuum on the optical path of exposure light EL in the vacuum chamber 1. The vacuum chamber 1 is, for example, one obtained by fixing a top part 1b onto a bottom part 1a. As an example, the pressure in the vacuum chamber 1 is approximately 10⁻⁵ Pa and the pressure in the sub-chamber (not shown) for housing the projection optical system PO in the vacuum chamber 1 is approximately 10⁻⁵-10⁻⁶ Pa.

The description hereinafter will proceed based on such a coordinate system in FIG. 1 that the Z-axis is taken along a direction of a normal to a surface (bottom surface of the vacuum chamber 1) where the wafer stage WST is mounted, the X-axis is perpendicular to the plane of FIG. 1 in a plane perpendicular to the Z-axis (plane substantially parallel to a horizontal plane in the present embodiment), and the Y-axis is parallel to the plane of FIG. 1. In the present embodiment, the illumination region 27R illuminated with the exposure light EL on the reticle R is an arcuate shape elongated in the X-direction (non-scan direction) and during normal exposure, the reticle R and wafer W are synchronously moved in the Y-direction (scan direction) relative to the projection optical system PO.

First, the laser plasma light source 10 is a light source of a gas jet cluster type having a high-output laser light source (not shown), a condenser lens 12, a nozzle 14, and a collector mirror 13. The condenser lens 12 condenses laser light supplied through a window member 15 of the vacuum chamber 1 from the laser light source. The nozzle 14 ejects a target gas such as xenon. The collector mirror 13 has a reflecting surface of an ellipsoidal shape. The pulsed exposure light EL emitted, e.g., at the frequency of several kHz from the laser plasma light source 10 is focused at the second focus of the collector mirror 13. The output of the laser plasma light source 10 is controlled by the main control system 31.

The exposure light EL focused at the second focus travels via a concave mirror 21 to become an almost parallel beam, the parallel beam of exposure light is then incident to a first fly's eye optical system 22 consisting of a plurality of mirrors. The exposure light EL reflected by the first fly's eye optical system 22 is incident to a second fly's eye optical system 23 consisting of a plurality of mirrors. This pair of fly's eye optical systems 22 and 23 constitute an optical integrator. The shape, arrangement, and others of each mirror element in the fly's eye optical systems 22, 23 are disclosed, for example, in U.S. Pat. No. 6,452,661.

In FIG. 1, the neighborhood of the reflecting surface of the second fly's eye optical system 23 (the neighborhood of the exit plane of the optical integrator) is a pupil plane of the illumination optical system ILS. At the position of the pupil plane or in the neighborhood thereof, an aperture stop (not shown) for switching an illumination condition to normal illumination, annular illumination, bipolar illumination, quadrupolar illumination, or the like is arranged. The exposure light EL passing through the aperture stop is incident to a curved mirror 24, the exposure light EL reflected on the curved mirror 24 is then reflected on a concave mirror 25, and then the exposure light EL illuminates the illumination region 27R on the pattern surface of the reticle R with a uniform illuminance distribution from below and in an oblique direction. There is a variable reticle blind (variable field stop) (not shown) provided for substantially defining the shape of the illumination region 27R and for opening and closing in the scan direction. The illumination optical system ILS is constructed including the concave mirror 21, fly's eye optical systems 22, 23, curved mirror 24, concave mirror 25, and so on. The illumination optical system ILS does not always have to be limited to the configuration of FIG. 1 and can be constructed in any of other various configurations.

Next, the reticle R is adsorbed and held through an electrostatic chuck RH on the bottom surface of the reticle stage RST. The reticle stage RST is driven by a stage control system 33, based on measured values with laser interferometers (not shown) and control information of the main control system 31. In concrete terms, the control system 33 drives the reticle stage RST so as to move in a predetermined stroke in the Y-direction, for example, through a drive system (not shown) consisting of a magnetic levitation type two-dimensional linear actuator, along a guide plane parallel to the XY plane on the outer surface of the vacuum chamber 1 and so as to also move by a small amount in the X-direction, in a direction of rotation around the Z-axis (θz direction), and so on. The reticle R is installed in the space surrounded by the vacuum chamber 1 through an aperture in the top surface of the vacuum chamber 1. A pa/titian 8 is provided so as to cover the reticle stage RST on the vacuum chamber 1 side and the interior of the partition 8 is maintained at a pressure between the atmospheric pressure and the pressure in the vacuum chamber 1 by an unrepresented vacuum pump.

The exposure light EL reflected on the illumination region 27R of the reticle R travels toward the projection optical system PO for forming a demagnified image of the pattern on the object plane (first plane), on the image plane (second plane). The projection optical system PO is constructed, for example, in such a configuration that six mirrors M1-M6 are held by a plurality of divided tubes 4A-4D (the details of which will be described later). The projection optical system PO is a reflective optical system which is not telecentric on the object plane side and which is almost telecentric on the image plane side, and a projection magnification thereof is a demagnification ratio of 1/4× or the like. The exposure light EL reflected on the illumination region 27R of the reticle R travels through the projection optical system PO to form a demagnified image of a part of the pattern of the reticle R in an exposure region 27W (region conjugate with the illumination region 27R) on the wafer W.

In the projection optical system PO, the exposure light EL from the reticle R is reflected upward (in the +Z direction) on a first mirror M1, then reflected downward on a second mirror M2, thereafter reflected upward on a third mirror M3, and reflected downward on a fourth mirror M4. Then the exposure light EL is reflected upward on a fifth mirror M5, and is reflected downward on a sixth mirror M6 to form an image of a part of the pattern of the reticle R on the wafer W. As an example, the projection optical system PO can be constituted by an non-coaxial optical system in which the optical axes of the mirrors M1-M6 do not match in common with the optical axis AX. In this case, an aperture stop (not shown) is located at or near a pupil plane near the reflecting surface of the mirror M2. The projection optical system PO does not always have to be the non-coaxial optical system and its configuration is optional.

The wafer W is adsorbed and held through an electrostatic chuck (not shown) on the wafer stage WST. The wafer stage WST is arranged on a guide surface arranged along the XY plane. The wafer stage WST is driven by the stage control system 33, based on measured values with laser interferometers (not shown) and control information of the main control system 31. In concrete terms, the control system 33 drives the reticle stage RST so as to move in predetermined strokes in the X-direction and in the Y-direction through a drive system (not shown), for example, consisting of a magnetic levitation type two-dimensional linear actuator and so as to also move in the θz direction and others if necessary.

An imaging characteristic measuring system 29 for measuring wavefront aberration of the projection optical system PO by shearing interferometry or by point diffraction interferometry (PDI method), for example, as disclosed in U.S. Pat. No. 6,573,997, is disposed near the wafer W on the wafer stage WST. The result of measurement by the imaging characteristic measuring system 29 is supplied to the main control system 31. Distortion, coma, spherical aberration, etc. can be determined from the wavefront aberration. When the wavefront aberration of the projection optical system PO is measured by the PDI method, a test reticle RT with pinhole patterns formed therein may be loaded instead of the reticle R. Besides the PDI method, it is also possible, for example, to use a double grating method or the like in which diffraction gratings are located corresponding to the object plane and the image plane of the projection optical system PO to cause shearing interference.

During exposure, the wafer W is arranged inside a partition 7, in order to prevent gas evolved from the resist on the wafer W, from adversely affecting the mirrors M1-M6 of the projection optical system PO. The partition 7 is provided with an aperture for letting the exposure light EL pass and the space in the partition 7 is evacuated by a vacuum pump (not shown) under control of the main control system 31.

For exposure in one shot area (die) on the wafer W, the illumination optical system ILS illuminates the illumination region 27R of the reticle R with the exposure light EL. The reticle R and the wafer W are synchronously moved (or synchronously scanned) at a predetermined speed ratio according to the demagnification ratio of the projection optical system PO and in the Y-direction with respect to the projection optical system PO. In this manner, the reticle pattern is printed by exposure in one shot area on the wafer W. Thereafter, the wafer stage WST is driven to implement step movements of the wafer W in the X-direction and in the Y-direction, and then the pattern of the reticle R is printed by scanning exposure in the next shot area on the wafer W. In this manner the image of the pattern of the reticle R is successively printed by exposure in a plurality of shot areas on the wafer W by the step-and-scan method.

The configuration of the projection optical system PO in the present embodiment will be described below in detail. The cylinder of the projection optical system PO is divided into first divided tube 4A, second divided tube 4B, third divided tube 4C, and fourth divided tube 4D. The divided tubes 4A and 4B are coupled to each other with bolts 5B at a plurality of positions to constitute a lower tube 6A. A flange portion 4Af is formed at an upper end of the divided tube 4A and the flange 4Af is fixed to an optical system frame 3 in the vacuum chamber 1 with bolts 5A at a plurality of positions. The divided tube 4C and the divided tube 4D are coupled to each other with bolts 5D and nuts 5B at a plurality of positions to constitute an upper tube 6B. A bottom surface of the divided tube 4C in the upper tube 6B is fixed to a top surface of the divided tube 4A in the lower tube 6A with bolts 5C at a plurality of positions. The height in the Z-direction (overall length) of the projection optical system PO is, for example, approximately from 1 meter to several meters.

The mirrors M1 and M3 are supported through respective holding and adjusting mechanisms 35A and 35C on a support plate 39A in the divided tube 4C. The holding and adjusting mechanism 35A (35C as well) is constructed including a mirror holder for holding the mirror M1 (M3) and coarse adjustment mechanisms 38 including hinge mechanisms at three locations for supporting the mirror holder. The coarse adjustment mechanisms 38 allow an operator to adjust the height thereof in the resolution of about 1 μm, for example, within the stroke range of several 10 μm to 100 μm, for example, through an aperture (not shown) provided in the divided tube 4C. By adjusting the coarse adjustment mechanisms 38 at three locations, it is possible to adjust the position of the mirror M1 (M3) in the direction of the optical axis AX, and angles around axes parallel to the X-axis and the Y-axis (or in the θx direction and θy direction) in a plane perpendicular to the optical axis AX.

The mirrors M2 and M4 are supported through respective holding and adjusting mechanisms 35B and 35D in the upper part of the divided tube 4D. The holding and adjusting mechanism 35B (35D as well) includes a mirror holder 36 for holding the mirror M2 (M4), fine adjustment mechanisms 37 consisting of parallel link mechanisms at three locations for supporting the mirror holder 36, and coarse adjustment mechanisms 38 at three locations for supporting these fine adjustment mechanisms 37. The fine adjustment mechanisms 37 enable adjustment in the resolution of about 1 nm within the stroke range of about several μm to 10 μm, for example, by drive devices such as piezoelectric devices. Expansion and contraction amounts of the fine adjustment mechanisms 37 are controlled by an imaging characteristic control system 34 placed under control of the main control system 31. By adjusting the fine adjustment mechanisms 37 at three locations, it is possible to adjust the position of the mirror M2 (M4) in the direction of the optical axis AX and angles in the θx direction and the θy direction.

The configurations of the fine adjustment mechanisms 37 and the coarse adjustment mechanisms 38 are described, for example, in U.S. Pat. No. 7,154,684.

The mirror M6 is supported through a holding and adjusting mechanism 35F (having the same configuration as the holding and adjusting mechanism 35A) on a support plate 39C in the divided tube 4A. In addition, the mirror M5 is supported through a holding and adjusting mechanism 35E (having the same configuration as the holding and adjusting mechanism 35B) on a support plate 39B in the divided tube 48. Accordingly, the mirrors M1-M6 constituting the projection optical system PO are arranged so that their position in the direction of the optical axis AX and angles in the θx direction and θy direction can be adjusted through the respective holding and adjusting mechanisms 35A-35F. The imaging characteristic control system 34 adjusts expansion and contraction amounts of the fine adjustment mechanisms 37 at three locations in the holding and adjusting mechanisms 35B, 35D, 35E. By this, predetermined aberrations such as distortion, coma, and spherical aberration of the projection optical system PO can be adjusted within a predetermined range (e.g., a range including the range of variation in imaging characteristic due to irradiation with the exposure light EL) during the exposure operation by the exposure apparatus 100. The configurations of the holding and adjusting mechanisms 35A-35E are optional and the combination of fine adjustment mechanisms 37 and coarse adjustment mechanisms 38 in each holding and adjusting mechanism 35A-35E is also optional.

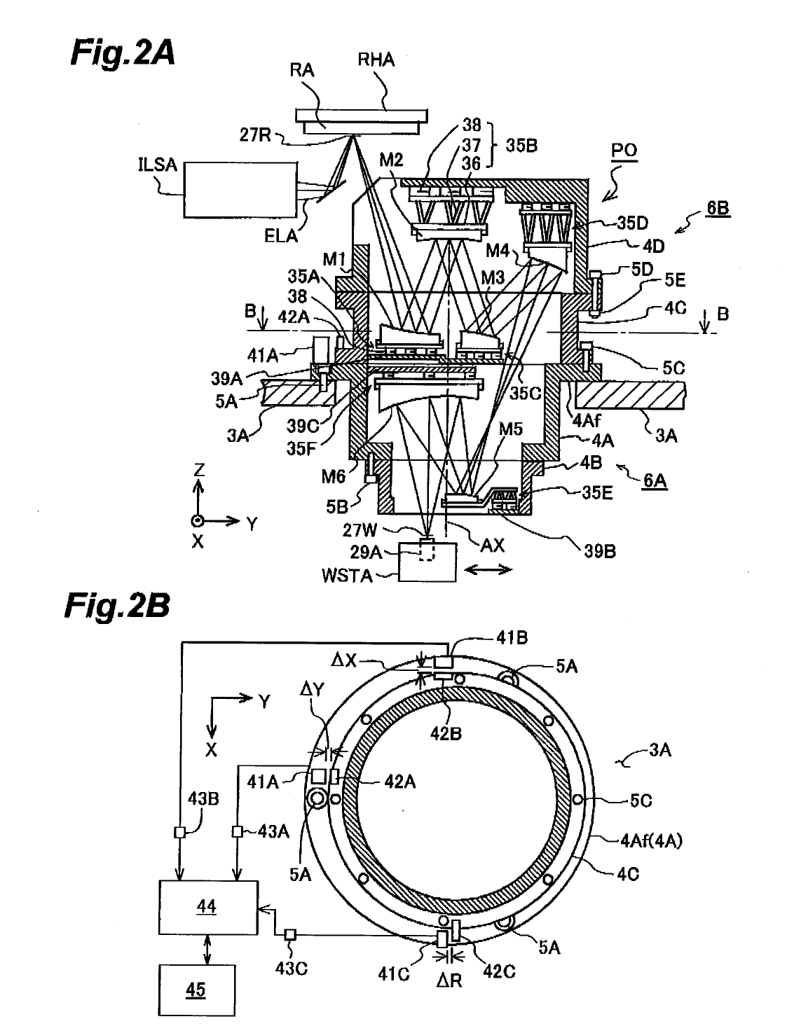

Furthermore, the divided tubes 4A, 4C of the projection optical system PO are provided with sensors for measuring a relative positional relation between them, as shown in FIG. 2B.

The sensors are, for example, capacitance sensors and are composed of detectors 41A, 41B, 41C for detecting an electrical change at a detection position, and members to be measured 42A, 42B, 42C consisting of electrodes of a flat plate shape arranged opposite to the respective detectors 41A, 41B, 41C.

In FIG. 2B, the detectors 41A, 41B, 41C are fixed at an end in the −Y direction and at two ends in the X-direction on the flange portion 4Af of the divided tube 4A. In addition, the members to be measured 42A, 42B, 42C are fixed to the divided tube 4C at portions opposed to the respective detectors 41A, 41B, 41C. The detectors 41A-41C are provided with respective connectors 43A-43C which can be connected to and disconnected from a processing unit 44 of detected signals or the like. The detectors 41A, 41B, 41C measure a Y-directional space ΔY, an X-directional space ΔX, and a circumferential space ΔR relative to the members to be measured 42A, 42B, 42C, from changes in capacitances to the respective members to be measured 42A, 42B, 42C on the divided tube 4C. An angle of rotation in the θz direction of the divided tube 4C relative to the divided tube 4A can also be calculated from a difference between the spaces ΔY and ΔR at the two locations.

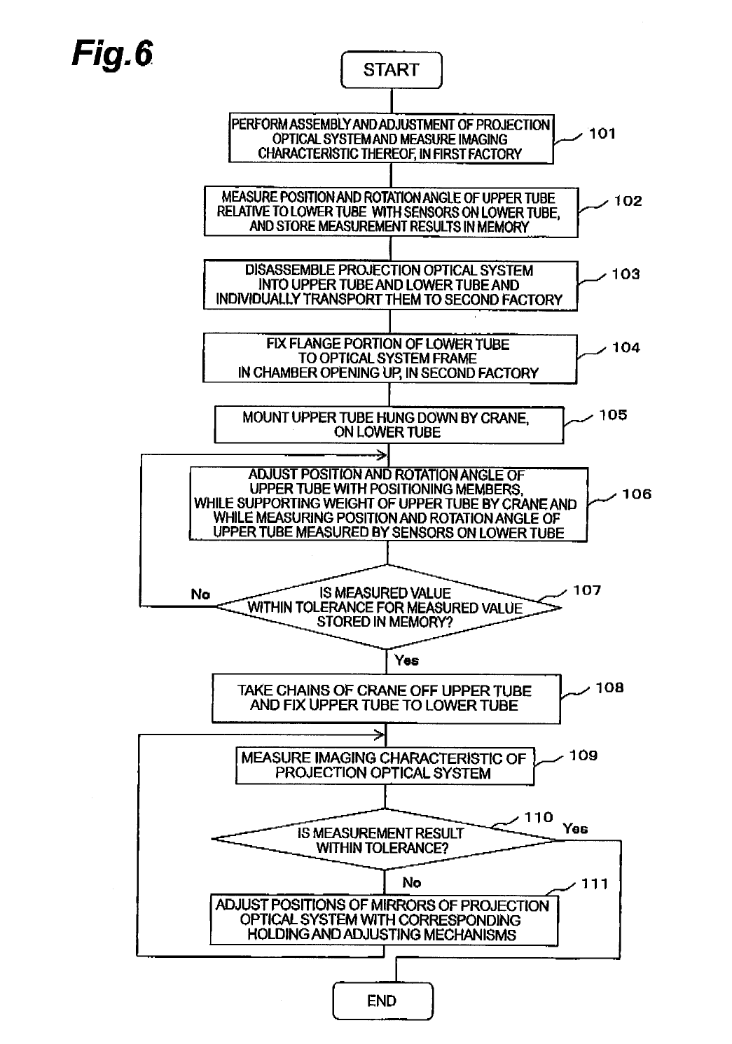

In addition to these detectors 41A-41C, it is optional to further provide at least three sensors for measuring the Z-directional position of the divided tube 4C relative to the divided tube 4A and angles of rotation in the θx direction and the θy direction. This configuration enables measurement of relative positions as six degrees of freedom of the upper tube 6B to the lower tube 6A. The detectors 41A-41C and others are omitted from the illustration in FIG. 1. An example of an assembly and adjustment method of the projection optical system PO according to the present embodiment will be described below with reference to the flowchart of FIG. 6.

First, in block 101, as shown in FIG. 2A, the flange portion 4Af of the divided tube 4A of the projection optical system PO is fixed to a predetermined optical system frame 3A in an optical system manufacturing factory (first factory). The same directions are defined in the coordinate system (X, Y, Z) in FIG. 2A as in the coordinate system (X, Y, Z) in FIG. 1. Then the assembly and adjustment of the other divided tubes 4B-4D are carried out with reference to the divided tube 4A. Specifically, the divided tube 4C is mounted on the divided tube 4A and fixed with bolts 5C while adjusting the position of the divided tube 4C with reference to the divided tube 4A. Next, the divided tube 4D is mounted on the divided tube 4C and fixed with bolts 5D and nuts SE while adjusting the position of the divided tube 4D with reference to the divided tube 4C already position-adjusted relative to the divided tube 4A. Furthermore, the divided tube 4B is brought toward the divided tube 4A from below and fixed with bolts 5B while adjusting the position of the divided tube 4B with reference to the divided tube 4A. After completion of these assembly and adjustment processes, the imaging characteristic is measured with an adjustment beam ELA and the positions and angles of the mirrors M1-M6 of the projection optical system PO are adjusted based on the result of the measurement. In FIG. 2A, the adjustment beam ELA emitted from an adjustment light source ELSA is guided via a mirror to illuminate an illumination region 27R on an adjustment reticle RA held through an electrostatic chuck RHA on an unrepresented frame. Since the projection optical system PO is the reflecting system, it is also possible to use a laser beam, for example, in the visible region which has a wavelength longer than that of the EUV light, as the adjustment beam ELA.

The adjustment beam ELA reflected on the adjustment reticle RA travels through the projection optical system PO to be incident to an exposure region 27W on an imaging characteristic measuring system 29A on a movable stage WSTA. The imaging characteristic measuring system 29A measures the wavefront aberration of the projection optical system PO as the imaging characteristic measuring system 29 shown in FIG. 1 does. However, in the case that the wavelength of the adjustment beam ELA is different from that of the EUV light, the period of internal diffraction gratings, and others are different from those of the imaging characteristic measuring system 29. Then the positions and angels of the mirrors M1-M6 of the projection optical system PO are adjusted until the wavefront aberration measured by the imaging characteristic measuring system 29A falls within a tolerance.

In next block 102, as shown in FIG. 2B which is a sectional view along line BB in FIG. 2A, the spaces ΔX, ΔY corresponding to X-directional and Y-directional positional deviations of the divided tube 4C relative to the divided tube 4A and the circumferential space ΔR corresponding to an angle of rotation in the θz direction are measured using the detectors 41A-41C at three locations provided on the divided tube 4A and the processing unit 44 connected thereto through the connectors 43A-43C, and the measurement results, corresponding to the relative positional relation of the divided tube 4A and the divided tube 4C, are stored in a memory 45, for example, of the USB (Universal Serial Bus) system. Thereafter, the connectors 43A-43C are taken off the processing unit 44 and the memory 45 is removed from the processing unit 44 and carried to an installation place of the projection optical system PO. The present example involves the measurements of the spaces ΔX, ΔY, and ΔR of the divided tube 4C relative to the divided tube 4A, but in next block 103 to transport the projection optical system PO in a divided state into the upper tube 6B and the lower tube 6A, the divided tube 4A and divided tube 4B, and, the divided tube 4C and divided tube 4D are transported as fixed to each other, and therefore the measurement results stored in the memory 45 are equivalent to stored data of the relative positional relation of the upper tube 6B relative to the lower tube 6A.

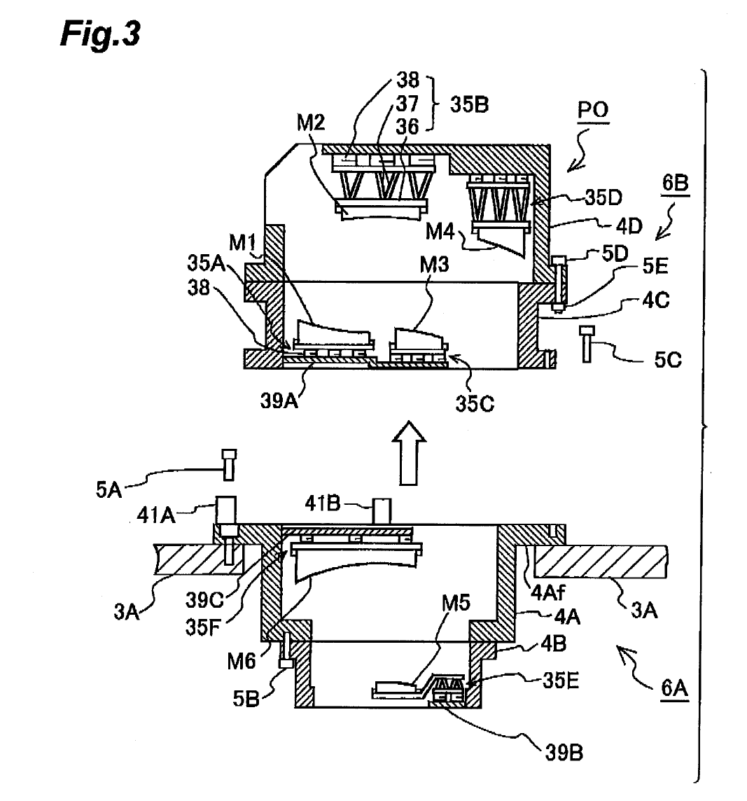

In next block 103, as shown in FIG. 3, the projection optical system PO is disassembled into the upper tube 6B and the lower tube 6A, and the upper tube 6B and the lower tube 6A are individually transported to a semiconductor device manufacturing factory (second factory) where the exposure apparatus 100 (projection optical system PO) is to be installed. On the occasion of transportation, the upper tube 6B and the lower tube 6A are packed with a packing material made of a material evolving little organic gas. By filling the interior with an inert gas such as nitrogen, it is feasible to transport them while maintaining the cleanliness of the divided tubes 4A-4D and the mirrors M1-M6.

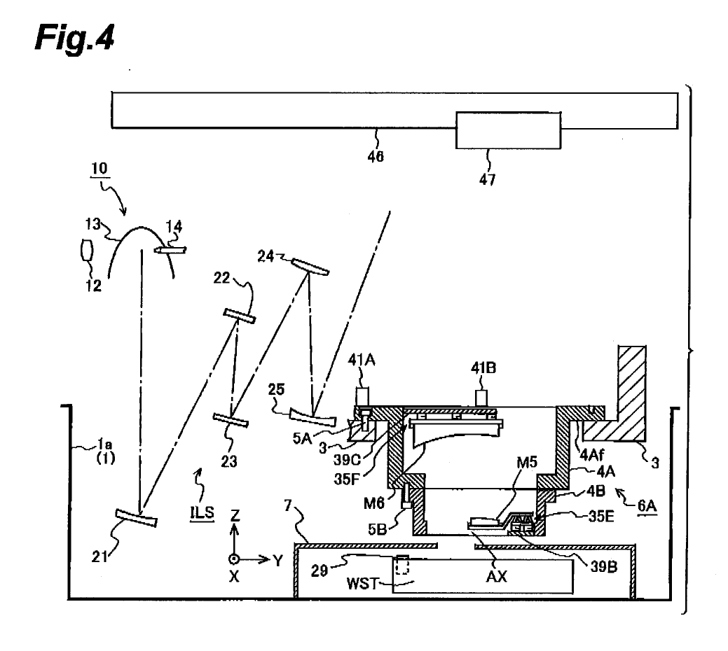

FIG. 4 is an exemplary sectional view showing the exposure apparatus in the middle of assembly at the installation place in the semiconductor device manufacturing factory. In FIG. 4, the bottom part 1a of the vacuum chamber 1 opening up is installed, the wafer stage WST is mounted in the bottom part 1a, and the laser plasma light source 10 and a part of the illumination optical system ILS are supported on a frame not shown.

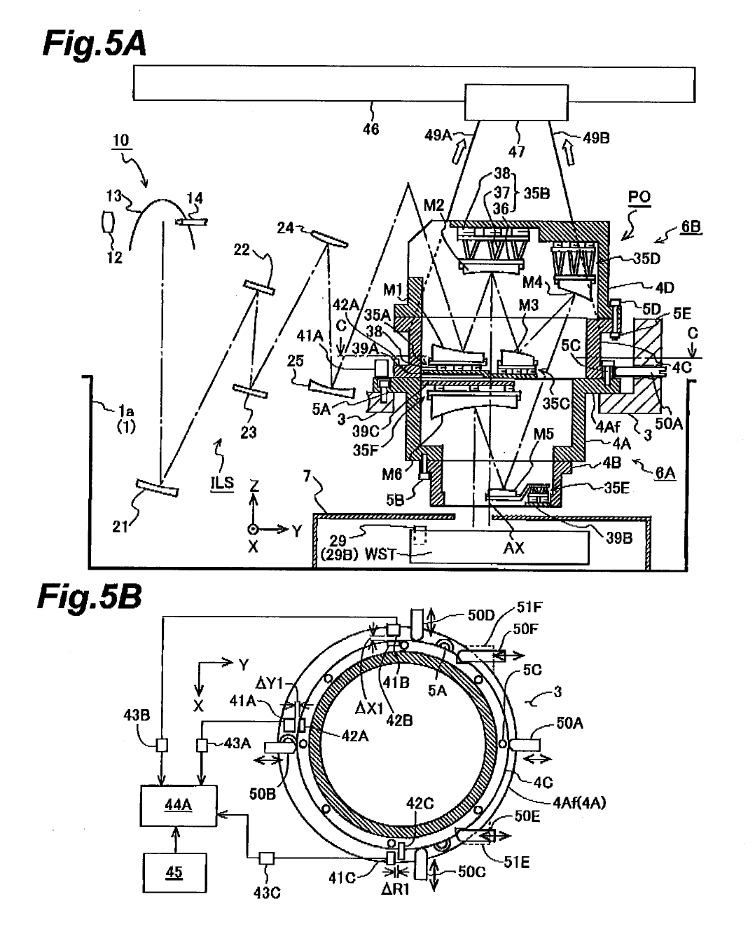

In next block 104, the flange portion 4Af of the divided tube 4A of the lower tube 6A is fixed with bolts 5A to the optical system frame 3 in the vacuum chamber 1 shown in FIG. 4. This work is carried out using a crane 47 which can move along a guide rail 46 arranged on a ceiling above the vacuum chamber 1. In next block 105, as shown in FIG. 5A, the upper tube 6B hanging down through chains 49A, 49B the length of which can be adjusted by the crane 47 is mounted onto the lower tube 6A of the projection optical system PO. In next block 106, the position and rotation angle of the upper tube 6B are adjusted using a positioning member 50A and others provided on the optical system frame 3, while canceling out part of weight by supporting the weight of the upper tube 6B by the crane 47 and while measuring the position and rotation angle of the upper tube 6B with the detectors 41A-41C provided on the divided tube 4A of the lower tube 6A.

As shown in FIG. 5B, which is an exemplary sectional view along line CC in FIG. 5A, the detectors 41A-41C at three locations provided on the divided tube 4A of the lower tube 6A are connected through the connectors 43A-43C to a processing unit 44A. The memory 45 storing the measurement results of the relative positional relation measured in block 102 is also connected to the processing unit 44A. The processing unit 44A is provided with a function to display the positions and rotation angles measured through the detectors 41A-41C and errors from the positions and rotation angles stored in the memory 45.

Fixed to the optical system frame 3 supporting the lower tube 6A are positioning members 50A, 50B of the locking screw type for pushing and pulling the upper tube 6B in the X-direction, and positioning members 50C, 50D of the locking screw type for pushing and pulling the upper tube 6B in the Y-direction. Furthermore, a pair of positioning members 50E, 50F for rotating the upper tube 6B in the θz direction are also fixed through respective support members 51E, 51F indicated by dotted lines, at almost symmetric positions in the ±X directions in the upper part of the divided tube 4A. By pushing and pulling the positioning members 50A-50F, it is possible to adjust the X-directional and Y-directional positions and the rotation angle in the θz direction of the upper tube 6B relative to the lower tube 6A. The positioning members 50A-50F are omitted from the illustration in FIG. 1.

In this case, the detectors 41A-41C and the processing unit 44A are used to measure the spaces ΔX1 and ΔY1 corresponding to the X-directional and Y-directional positional deviations and the circumferential space ΔR1 corresponding to the rotation angle in the θz direction of the upper tube 6B (divided tube 4C) relative to the lower tube 6A (divided tube 4A).

In next block 107, an operator determines whether the measured spaces ΔX1, ΔY1, and ΔR1 are within respective tolerances with respect to the stored spaces ΔX, ΔY, and ΔR, by using the measured values (corresponding to the relative positional relation of the divided tube 4A and the divided tube 4C which is equivalent to the upper tube 6A and the lower tube 6B) measured in block 102 and stored in the memory 45. The tolerances are, for example, approximately from ±several μm to ±10 μm. In the case that the measurement results are not within the tolerances with respect to the measured values stored, the flow returns to block 106 to adjust the position and rotation angle of the upper tube 6B with the positioning members 50A-50F provided on the optical system frame 3 and others while measuring the position and rotation angle of the upper tube 6B (divided tube 4C) with the detectors 41A-41C.

Thereafter, when block 107 results in determining that the measured values of the positional relation are within the tolerances with respect to the measured values stored, the flow moves to block 108 to take the chains 49A, 49B of the crane 47 off the upper tube 6B and to fix the divided tube 4C of the upper tube 6B to the flange portion 4Af of the divided tube 4A of the lower tube 6A with bolts 5C. Next block 109 is to measure the wavefront aberration (imaging characteristic) of the projection optical system PO with the imaging characteristic measuring system 29. For using the imaging characteristic measuring system 29, it is necessary to assemble the vacuum chamber 1 as shown in FIG. 1 and to evacuate the interior thereof to vacuum. Then, in order to measure the wavefront aberration of the projection optical system PO in the state of FIGS. 5A and 5B, it is also allowable to set an imaging characteristic measuring system 29B capable of using measurement light, e.g., in the visible region, instead of the imaging characteristic measuring system 29, as in the case of block 101, and to illuminate a predetermined reflective pattern (not shown) on the object, plane of the projection optical system PO with the measurement light.

Next block 110 is to check whether the measurement result of the wavefront aberration is within a tolerance. This tolerance is an adjustable range by the fine adjustment mechanisms 37 of the holding and adjusting mechanisms 35A-35F supporting the mirrors M1-M6.

When the measurement result of the wavefront aberration is not within the tolerance, the flow moves to block 111 to adjust the positions of the respective mirrors M1-M6 of the projection optical system PO with the coarse adjustment mechanisms 38 in the corresponding holding and adjusting mechanisms 35A-35F. Thereafter, the operation returns to block 109. The adjustment of the positions of the mirrors M1-M6 in block 111 is carried out until the measurement result of the wavefront aberration falls within the tolerance. When block 110 results in determining that the measurement result of the wavefront aberration is within the tolerance, the assembly and adjustment of the projection optical system PO are completed. A variation or error in the imaging characteristic of the projection optical system PO after this point can be corrected by driving the fine adjustment mechanisms 37 in the holding and adjusting mechanisms 35A-35B by the imaging characteristic control system 34.

As described above, the present embodiment involves the transportation of the projection optical system PO in the divided state into the lower tube 6A and the upper tube 6B, but the assembly and adjustment of the projection optical system PO can be readily and efficiently carried out in the factory where the exposure apparatus 100 is used, thereby almost exactly restoring the state of assembly and adjustment in the optical system manufacturing factory.

The actions, effects, and others of the present embodiment are as described below.

(1) The projection optical system PO of the exposure apparatus 100 of the present embodiment is the projection optical system having the plurality of mirrors M1-M6, the lower tube 6A holding the mirrors M5, M6 out of the mirrors M1-M6, and the upper tube 6B fixed to the lower tube 6A and holding the mirrors M1-M4 out of the mirrors M1-M6, and configured to form the image of the pattern on the first plane, on the second plane, and is provided with the memory 45 storing the relative positional relation (ΔX, ΔY, ΔR) between the lower tube 6A and the upper tube 6B measured in the state in which the upper tube 6B is fixed to the lower tube 6A and in which the wavefront aberration (optical property) is adjusted as the imaging characteristic of the projection optical system PO.

The assembly method of the projection optical system PO includes the blocks 101, 102 of storing the relative positional relation between the lower tube 6A and the upper tube 6B in the state in which the upper tube 6B is fixed to the lower tube 6A and in which the wavefront aberration of the projection optical system PO is adjusted, the block of disassembling the lower tube 6A and the upper tube 6B (the first half of block 103), the block of adjusting the relative positions of the lower tube 6A and the upper tube 6B, by using the relative positional relation stored, in again fixing the disassembled lower tube 6A and upper tube 6B to each other (the second half of block 103 to block 107), and the block 108 of fixing the upper tube 6B to the lower tube 6A.

This embodiment involves storing the relative positional relation between the lower tube 6A and the upper tube 6B measured in the state in which the upper tube 6B is fixed to the lower tube 6A and in which the wavefront aberration of the projection optical system PO is adjusted. Then the projection optical system PO is disassembled into the two partial tubes and conveyed to the installation place and the two partial tubes are coupled to each other so as to almost reproduce the relative positional relation, thereby implementing the assembly and adjustment of the projection optical system PO. Therefore, even when the projection optical system PO has a long total length, it can be readily installed at a necessary installation place and the assembly and adjustment of the projection optical system PO at the installation place can be carried out in a short period of time.

The projection optical system PO can be disassembled into three divided parts and conveyed in that state.

Instead of the use of the memory 45, the below-described detectors 41A-41C may be provided with respective memory devices for storing the measured values, so that each detector 41A-41C can store the measured value.

(2) The detectors 41A-41C for measuring the relative positional relation are provided on the divided tube 4A of the lower tube 6A and the members to be measured 42A-42C are provided on the divided tube 4C of the upper tube 6B; therefore, the relative positional relation can be accurately measured.

It is a matter of course that the detectors 41A-41C can be located on the upper tube 6B side and the members to be measured 42A-42C can be located on the lower tube 6A side. The relative positional relation between the lower tube 6A and the upper tube 6B may be measured using only the detectors 41A-41C, without using the members to be measured 42A-42C.

At least one of the detectors 41A-41C may be provided on at least one of the lower tube 6A and the upper tube 6B. For example, in the case that the lower tube 6A or the upper tube 6B is provided with a stopper or rail to position the tube and if the X-directional and Y-directional positions can be regulated within the ranges where they can be adjusted by the fine adjustment mechanisms, it is sufficient that the relative positional relation between the lower tube 6A and the upper tube 6B is measured with the detectors corresponding to θz. Of course, this modification is not limited to the foregoing directions and the same also applies similarly to the six degrees of freedom, X-direction, Y-direction, Z-direction, θx direction, θy direction, and θz direction, with installation of corresponding detectors.

The detectors 41A-41C may be, for example, eddy current sensors, or optical detectors of the triangulation method or the like. Furthermore, the relative positional relation may also be measured by providing absolute type linear encoders as the detectors 41A-41C, using scales (or diffraction gratings) provided on the upper tube 6B (divided tube 4C), as the members to be measured 42A-42C, and reading displacements of the scales by the linear encoders.

At least one of the detectors 41A-41C and the members to be measured 42A-42C may be provided in a detachable state or may be fixed to the lower tube 6A or the upper tube 6B.

(3) The optical system frame 3 is provided with the positioning members 50A-50D (adjusting devices) for adjusting the relative position of the upper tube 6B to the lower tube 6A, and the lower tube 6A is provided with the positioning members 50E, 50F for adjusting the relative rotation angle of the upper tube 6B to the lower tube 6A through the support members 51E, 51F. Therefore, the relative position and rotation angle of the upper tube 6B to the lower tube 6A can be readily adjusted with high accuracy.

The positioning members 50A-50D may also be fixed to the lower tube 6A. Furthermore, all the positioning members 50A-50F can be fixed to the optical system frame 3.

At least one of the positioning members 50A-50F may be composed of an electric actuator. Furthermore, at least one of the positioning members 50A-50F may be constructed in a detachable configuration.

(4) The upper tube 6B is fixed with reference to the divided tube 4A of the lower tube 6A having the flange portion 4Af, the assembly, and therefore, adjustment are easy.

(5) The blocks 101, 102 of storing the relative positional relation between the lower tube 6A and upper tube 6B have the block of fixing the upper tube 6B to the lower tube 6A to assemble the projection optical system PO (the first half of block 101), the block of measuring the imaging characteristic (wavefront aberration) of the assembled projection optical system PO (the second half of block 101), and the block of storing the relative positional relation (ΔX, ΔY, ΔR) between the lower tube 6A and the upper tube 6B (the second half of block 102). Therefore, the positional relation between the lower tube 6A and the upper tube 6B can be stored in the state in which the assembly and adjustment of the projection optical system PO are completed.

(6) The block of adjusting the relative position includes the block 106 of adjusting the relative position of the upper tube 6B to the lower tube 6A in the state in which the crane 47 is used to cancel out at least part of the weight (load) of the upper tube 6B on the lower tube 6A. Therefore, the relative position of the upper tube 6B to the lower tube 6A can be readily adjusted even if the weight of the upper tube 6B is large.

In the case that the weight of the upper tube 6B is small, the relative position of the upper tube 6B to the lower tube 6A may be adjusted in a state in which the entire weight of the upper tube 6B is supported on the lower tube 6A.

(7) The block 109 of measuring the imaging characteristic (wavefront aberration) of the projection optical system PO is executed after the fixing block 108, and therefore, it can be checked whether the assembly and adjustment of the projection optical system PO are carried out with high accuracy.

When the present embodiments are applied, for example, to the exposure apparatus using an ArF excimer laser or the like, the operations of blocks 109 to 111 can be omitted because the relative position accuracy among the plurality of optical elements of the projection optical system is relatively low in that case.

(8) Furthermore, the blocks 109 to 111 can be omitted when the holding and adjusting mechanisms 35A-35E can hold the optical elements so as to keep the measurement result of wavefront aberration within the range adjustable by the fine adjustment mechanisms 37 even through the blocks 102 to 108. Namely, completion of block 108 leads to an end of the assembly and adjustment of the projection optical system PO. A variation or error in the imaging characteristic of the projection optical system PO after this block can be corrected by driving the fine adjustment mechanisms 37 in the holding and adjusting mechanisms 35A-35E by the imaging characteristic control system 34. It is a matter of course that the imaging characteristic of the projection optical system PO can be measured at this point and corrected based on the result thereof. It is also allowable to compare the measurement result with the imaging characteristic measured in block 101 and to perform the correction based on the result of the comparison.

(9) The disassembling block (the first half of block 103) is to disassemble the lower tube 6A and the upper tube 6B in the optical system manufacturing factory (first place) (outside the chamber) and the block of adjusting the relative positions thereof has the block of transporting the lower tube 6A and the upper tube 6B disassembled in the optical system manufacturing factory, into the bottom part of the vacuum chamber 1 in the device manufacturing factory (second place) (the second half of block 103), and the block 106 of adjusting the relative positions of the lower tube 6A and the upper tube 6B in the bottom part of the vacuum chamber 1 (inside the chamber). Therefore, even if the lower tube 6A and the upper tube 6B are transported in the disassembled state, the relative positions of the lower tube 6A and the upper tube 6B can be readily set in the state before disassembled.

The present embodiments are also applicable to a situation in which the projection optical system PO is disassembled in a certain room in a factory and conveyed to another room in the same factory and in which the assembly and adjustment thereof are then carried out in the other room.

When the present embodiment is applied, for example, to the exposure apparatus using the ArF excimer laser beam, the place where the assembly and adjustment of the projection optical system are finally carried out is an interior of an ordinary environment chamber used under the atmospheric pressure, for example. Furthermore, the place where the assembly and adjustment of the projection optical system are finally carried out may be outside the chamber.

(10) The mirrors M1-M6 of the projection optical system PO are equipped with the holding and adjusting mechanisms 35A-35F (adjusting mechanisms) including the fine adjustment mechanisms 37 and/or the coarse adjustment mechanisms 38. Therefore, errors of the relative positions among the mirrors M1-M6 remaining after the adjustment of the relative positional relation between the lower tube 6A and the upper tube 6B can be adjusted using the holding and adjusting mechanisms 35A-35F.

The projection optical system may be configured merely in such a configuration that at least one mirror out of the mirrors M1-M6 is provided with any one of the holding and adjusting mechanisms 35A-35F.

(11) The exposure apparatus 100 of the present embodiment is the exposure apparatus for exposing the wafer W through the projection optical system PO, which has the memory 45 for storing the relative positional relation between the lower tube 6A and the upper tube 6B measured in the state in which the upper tube 6B is fixed to the lower tube 6A of the projection optical system PO and in which the wavefront aberration of the projection optical system PO is adjusted, and the positioning members 50A-50F for adjusting the relative positions of the lower tube 6A and the upper tube 6B, based on the relative positional relation stored in the memory 45.

Therefore, after the disassembly and transportation of the projection optical system PO, the assembly and adjustment of the projection optical system PO can be readily carried out with reproducibility.

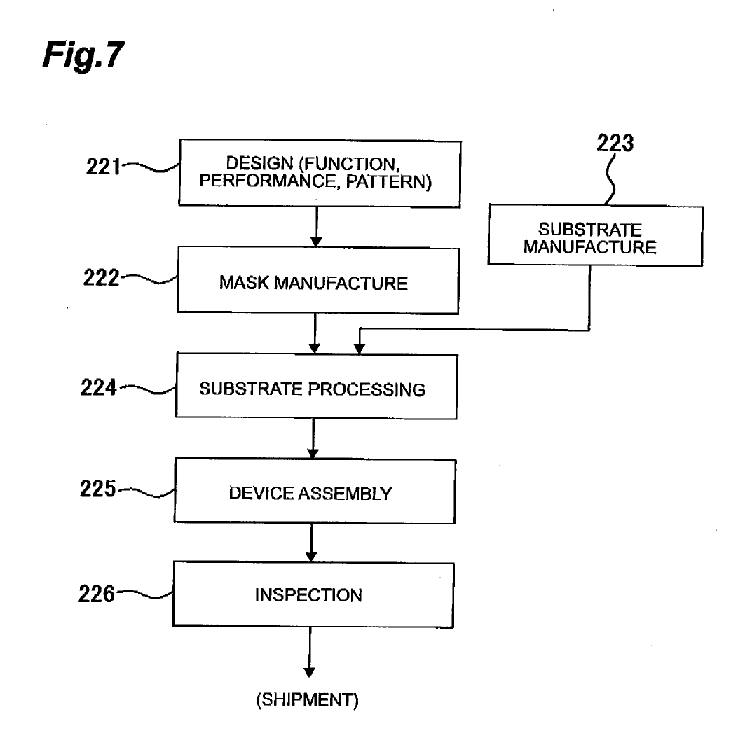

When electronic devices (or micro devices) such as semiconductor devices are manufactured using the exposure apparatus of the above embodiment, the electronic devices are manufactured, as shown in FIG. 7, through block 221 of designing the function and performance of the electronic devices, block 222 of manufacturing a mask (reticle) based on the design block, block 223 of manufacturing a substrate (wafer) which is a base of devices, and coating the substrate with a resist, substrate processing block 224 including a block of printing a pattern of the reticle on the substrate (photosensitive substrate) by exposure using the exposure apparatus of the foregoing embodiment, a block of developing the exposed substrate, blocks of heating (curing) and etching the developed substrate, and so on, device assembly block (including processing processes such as a dicing block, a bonding block, and a packaging block) 225, inspection block 226, and so on.

Therefore, this device manufacturing method includes forming the pattern on the photosensitive layer on the substrate by the exposure apparatus of the above embodiment and processing the substrate with the pattern formed thereon (block 224). Since the exposure apparatus is configured to allow the easy assembly and adjustment of the projection optical system, it can reduce the manufacturing cost of electronic devices.

The embodiment shown in FIG. 1 uses the EUV light source as the exposure light source, but, without having to be limited to this, it is also possible, for example, to use a VUV light source at wavelengths of about 100-160 nm, an ultraviolet pulsed laser light source such as an Ar₂ laser (wavelength 126 nm), a Kr₂ laser (wavelength 146 nm), or an F₂ laser (wavelength 157 nm), an ArF excimer laser light (wavelength 193 nm) or KrF excimer laser light source (wavelength 247 nm), a harmonic generating light source of YAG laser, a harmonic generating device of solid-state laser (semiconductor laser or the like), or a mercury lamp (i-line or other lines).

The present embodiments are not limited to the reflection type projection optical systems, but can also be applied to catadioptric projection optical systems and dioptric projection optical systems.

Furthermore, the present embodiments are also applicable to the projection optical systems of liquid immersion type exposure apparatus, for example, as disclosed in U.S. Patent Application Laid-Open No. 2007/242247 or in European Patent Application Laid-Open No. 1420298.

The invention is not limited to the foregoing embodiments but various changes and modifications of its components may be made without departing from the scope of the present invention. Also, the components disclosed in the embodiments may be assembled in any combination for embodying the present invention. For example, some of the components may be omitted from all the components disclosed in the embodiments. Further, components in different embodiments may be appropriately combined.

What is claimed is:

1. A method of assembling a projection optical system which has a plurality of optical elements, a first partial tube holding a first optical element out of the plurality of optical elements, and a second partial tube holding a second optical element out of the plurality of optical elements and which is configured to form an image of a pattern on a first surface, on a second surface, the method comprising:
storing a relative positional relation between the first partial tube and the second partial tube, the relative positional relation being measured in a state in which the second partial tube is fixed to the first partial tube and in which an optical characteristic of the projection optical system is adjusted;
disassembling the first partial tube and the second partial tube;
adjusting, for again fixing the first partial tube and the second partial tube disassembled, relative positions of the first partial tube and the second partial tube, by using the relative positional relation stored; and
fixing the second partial tube to the first partial tube.

2. A method according to claim 1, wherein, in the adjusting, the relative positional relation of the first partial tube and the second partial tube is adjusted by moving at least one of the first partial tube and the second partial tube such that the relative positional relation of the first partial tube and the second partial tube to be adjusted falls within a predetermined tolerance, with respect to the relative positional relation stored.

3. A method according to claim 1, wherein, in the storing, a measurement result, measured with a sensor at least a part of which is provided on at least one of the first partial tube and the second partial tube, is stored.

4. A method according to claim 1, wherein the storing comprises:
fixing the second partial tube to the first partial tube to assemble the projection optical system;
measuring an optical characteristic of the projection optical system thus assembled; and
storing the relative positional relation between the first partial tube and the second partial tube.

5. A method according to claim 1, wherein, in the adjusting, the relative position of the second partial tube to the first partial tube is adjusted in a state in which at least a part of a weight of the second partial tube on the first partial tube is canceled out.

6. A method according to claim 1, further comprising measuring an optical characteristic of the projection optical system, after the fixing.

7. A method according to claim 6, further comprising:
comparing the optical characteristic of the projection optical system measured in the measuring with the optical characteristic of the projection optical system measured upon storing the relative positional relation in the storing; and
adjusting a position of at least one optical element out of the plurality of optical elements, by using a result of the comparison in the comparing of the optical characteristic.

8. A method according to claim 7, wherein the position of at least one optical element out of the plurality of optical elements is adjusted by moving at least one of the first partial tube and the second partial tube such that the difference between the optical characteristics, which is obtained in the comparing, falls within a predetermined tolerance.

9. A method according to claim 1, wherein, in the disassembling, the first partial tube and the second partial tube are disassembled at a first place, and
wherein the adjusting comprises:
transporting the first partial tube and the second partial tube disassembled at the first place, to a second place; and
adjusting the relative positions of the first partial tube and the second partial tube, at the second place.

10. A method according to claim 9, wherein the first place is outside a chamber housing the projection optical system, and the second place is inside the chamber, and
wherein, in the adjusting at the second place, the relative positions of the first partial tube and the second partial tube is adjusted inside the chamber.

11. A method according to claim 10, wherein the first partial tube has a flange portion, and
wherein, in the fixing, the flange portion is fixed to a frame provided in the chamber.

12. A method according to claim 9, wherein the first place is located in an optical system manufacturing factory which manufactures the projection optical system, and the second place is located in a device manufacturing factory.

13. A method according to claim 12, wherein, in the disassembling, the first partial tube and the second partial tube are disassembled in the optical system manufacturing factory,
wherein, in the adjusting at the second place, the first partial tube and the second partial tube, which are disassembled in the optical system manufacturing factory, are transported into a chamber for exposure apparatus which is installed in the device manufacturing factory, and
wherein, in the adjusting at the second place, the relative positions of the first partial tube and the second partial tube is adjusted in the chamber for exposure apparatus.

14. A method according to claim 1, wherein the projection optical system is configured to form the image of the pattern on the first surface, on the second surface, by using EUV light.

15. A projection optical system configured to form an image of a pattern on a first surface, on a second surface, the projection optical system comprising:
a plurality of optical elements;
a first partial tube holding a first optical element out of the plurality of optical elements;
a second partial tube fixed to the first partial tube and holding a second optical element out of the plurality of optical elements, and
a memory device storing a relative positional relation between the first partial tube and the second partial tube, the relative positional relation being measured in a state in which the second partial tube is fixed to the first partial tube and in which an optical characteristic of the projection optical system is adjusted.

16. A projection optical system according to claim 15, further comprising an adjustment device adjusting the relative positional relation between the first partial tube and the second partial tube, at least a part of the adjustment device being provided on at least one of the first partial tube and the second partial tube.

17. A projection optical system according to claim 15, wherein the first partial tube serves as a reference in fixing the second partial tube to the first partial tube.

18. A projection optical system according to claim 15, wherein the first partial tube has a flange portion.

19. A projection optical system according to claim 15, further comprising a sensor measuring the relative positional relation, the sensor including a detector and a member to be measured,
wherein at least the detector is provided on at least one of the first partial tube and the second partial tube.

20. A projection optical system according to claim 15, further comprising an adjustment mechanism adjusting a position of at least one optical element out of the plurality of optical elements.

21. A projection optical system according to claim 15, wherein the projection optical system is configured to form the image of the pattern on the first surface, on the second surface, by using EUV light.

22. An exposure apparatus configured to expose an object through a projection optical system, wherein the projection optical system includes a projection optical system according to claim 15.

23. An exposure apparatus configured to expose an object through a projection optical system, wherein the projection optical system has a plurality of optical elements, a first partial tube holding a first optical element out of the plurality of optical elements, and a second partial tube fixed to the first partial tube and holding a second optical element out of the plurality of optical elements, the exposure apparatus comprising:
a memory device storing a relative positional relation between the first partial tube and the second partial tube, the relative positional relation being measured in a state in which the second partial tube is fixed to the first partial tube and in which an optical characteristic of the projection optical system is adjusted; and
an adjustment device adjusting relative positions of the first partial tube and the second partial tube, by using the relative positional relation stored in the memory device.

24. An exposure apparatus according to claim 23, wherein the adjustment device is provided on at least one of the first partial tube and the second partial tube.

25. An exposure apparatus according to claim 23, wherein the first partial tube has a flange portion, and the exposure apparatus further comprising a frame supporting the flange portion and having at least a part of the adjustment device.

26. An exposure apparatus according to claim 23, wherein the adjustment device adjusts the relative positional relation of the first partial tube and the second partial tube by moving at least one of the first partial tube and the second partial tube such that the relative positional relation of the first partial tube and the second partial tube to be adjusted falls within a predetermined tolerance, with respect to the relative positional relation stored.

27. A device manufacturing method comprising a lithography, wherein, in the lithography, an exposure apparatus according to claim 22.
